(19) United States
(12) Patent Application Publication
(10) Pub. No.: US 2023/0007783 A1
(43) Pub. Date: Jan. 5, 2023

(54) METHOD FOR PRODUCING WIRING CIRCUIT BOARD

(71) Applicant: NITTO DENKO CORPORATION, Osaka (JP)

(72) Inventors: Masaki ITO, Osaka (JP); Hayato TAKAKURA, Osaka (JP); Kenya TAKIMOTO, Osaka (JP)

(73) Assignee: NITTO DENKO CORPORATION, Osaka (JP)

(21) Appl. No.: 17/783,206

(22) PCT Filed: Nov. 27, 2020
(86) PCT No.: PCT/JP2020/044169

§ 371 Date: Jun. 7, 2022

(30) Foreign Application Priority Data
Dec. 10, 2019 (JP) 2019-222680

(51) Int. Cl. H05K 3/06

(52) U.S. Cl. CPC H05K 3/064; G03F 7/094

(57) ABSTRACT

A method for producing a wiring circuit board includes first forming a base insulating layer, and second forming a first wiring and a second wiring having different thicknesses from each other in order. The second step includes, in order, forming a seed film, forming a first resist in a reversed pattern of the first wiring on one surface in a thickness direction of the seed film, forming the first wiring on one surface in the thickness direction of the seed film by plating, removing the first resist, of forming a second resist in a reversed pattern of the second wiring on one surface in the thickness direction of the seed film to cover the first wiring, forming the second wiring on one surface in the thickness direction of the seed film by plating, removing the second resist, and removing the seed film.

### TECHNICAL FIELD

The present invention relates to a method for producing a wiring circuit board.

### BACKGROUND ART

Conventionally, a method for producing a suspension board in which wirings having different thicknesses are formed on the upper surface of a base insulating layer has been known.

For example, a method for producing a suspension board in which a write wiring, and a read wiring thicker than the write wiring are formed on the upper surface of the base insulating layer has been proposed (ref: for example, Patent Document 1 below).

In the production method described in Patent Document 1, the entire write wiring and a lower-side portion of the read wiring are formed by plating, and thereafter, an upper-side portion of the read wiring is formed by plating.

Specifically, in the production method described in Patent Document 1, before forming the lower-side portion of the read wiring, a first resist layer is formed in a reversed pattern of the write wiring and the read wiring, subsequently, the write wiring and the lower-side portion of the read wiring are formed by plating, thereafter, a second resist layer is formed in a reversed pattern of the read wiring, and subsequently, the upper-side portion of the read wiring is formed by plating.

### CITATION LIST

### Patent Document

Patent Document 1: Japanese Unexamined Patent Publication No. 2010-067317

### SUMMARY OF THE INVENTION

### Problem to be Solved by the Invention

However, in the method described in Patent Document 1, the method for forming the second resist layer in a reversed pattern of the read wiring around a portion where the lower-side portion of the read wiring is formed may include a tolerance between the lower-side portion of the read wiring and the reversed pattern of the second resist layer. Therefore, a deviation occurs between the lower-side portion of the read wiring and the reversed pattern of the second resist layer. Then, when such a second resist layer is used for plating, there is a problem that the read wiring which does not have a desired shape, arrangement, and size may be formed.

The present invention provides a method for producing a wiring circuit board capable of forming a first wiring or a second wiring having a desired shape, arrangement, and size.

### Means for Solving the Problem

The present invention (1) includes a method for producing a wiring circuit board including a first step of forming an insulating layer, and a second step of forming a first wiring and a second wiring having different thicknesses from each other in order on one surface in a thickness direction of the insulating layer, wherein the second step includes, in order, a step of forming a seed film on one surface in the thickness direction of the insulating layer, a step of forming a first resist in a reversed pattern of the first wiring on one surface in the thickness direction of the seed film, a step of forming the first wiring on one surface in the thickness direction of the seed film exposed from the first resist by plating, a step of removing the first resist, a step of forming a second resist in a reversed pattern of the second wiring on one surface in the thickness direction of the seed film so as to cover the first wiring, a step of forming the second wiring on one surface in the thickness direction of the seed film exposed from the second resist by plating, a step of removing the second resist, and a step of removing the seed film exposed from the first wiring and the second wiring.

In the production method, in the second step, since each of the first wiring and the second wiring having different thicknesses from each other is formed using each of the first resist and the second resist, it is possible to form the first wiring and the second wiring having a desired shape, arrangement, and size.

The present invention (2) includes the method for producing a wiring circuit board described in (1), wherein in the step of removing the first resist, the seed film remains.

When the seed film is formed in advance on one surface in the thickness direction of the base insulating layer, thereafter, a plating film is grown on the seed film exposed from the first resist, and then, the first resist layer is removed, since the seed film is usually extremely thin, it is removed along with the above-described first resist. Therefore, it is necessary to form the seed film again before forming the second resist.

However, in this method, since the first resist is removed so that the seed film remains, it is not necessary to form the seed film again before forming the second resist. Therefore, the seed film can be reused. As a result, it is possible to form the second wiring with few steps.

The present invention (3) includes the method for producing a wiring circuit board described in (1) or (2), wherein the second wiring is thicker than the first wiring.

When the first wiring is thicker than the second wiring, first, the first wiring is formed using the thick first resist. Then, when the thin second resist is formed, it is difficult to reliably mask the thick first wiring by such a second resist.

However, in the production method, since the first wiring is thinner than the second wiring, when the first wiring is first formed using the thin first resist, and thereafter, the thick second resist is formed, it is possible to easily and reliably mask the thin first wiring by such a second resist.

The present invention (4) includes the method for producing a wiring circuit board described in any one of (1) to (3), wherein the second wiring is independent of the first wiring.

According to the production method, since the second wiring is independent of the first wiring, it is possible to use the second wiring for a different application.

The present invention (5) includes the method for producing a wiring circuit board described in any one of (1) to (4), wherein the seed film has a thickness of 50 nm or more and 1000 nm or less.

According to the production method, in the step of removing the first resist, even when a removal method such as etching and peeling is carried out, the seed film having a thickness of 50 nm or more can reliably remain. Therefore, it is possible to stably carry out the plating in forming the second wiring. On the other hand, since the seed film has a thickness of 1000 nm or less, it is possible to form the seed film in a short time.

### Effect of the Invention

In the method for producing a wiring circuit board of the present invention, it is possible to form a first wiring or a second wiring having a desired shape, arrangement, and size.

### BRIEF DESCRIPTION OF THE DRAWINGS

FIGS. 1A to 1J show production process views of one embodiment of a method for producing a wiring circuit board of the present invention:

FIG. 1A illustrating a first step of forming a base insulating layer,

FIG. 1B illustrating a fourth step of forming a seed film,

FIG. 1C illustrating a fifth step of forming a first resist,

FIG. 1D illustrating a sixth step of forming a first wiring,

FIG. 1F illustrating a seventh step of removing the first resist,

FIG. 1F illustrating an eighth step of forming a second resist,

FIG. 1G illustrating a ninth step of forming a second wiring,

FIG. 1H illustrating a tenth step of removing the second resist,

FIG. 1I illustrating a eleventh step of removing the seed film, and

FIG. 1J illustrating a third step of forming a cover insulating layer.

FIG. 2 shows a cross-sectional view of a wiring circuit board corresponding to FIG. 1J and a view illustrating an embodiment in which a seed film is included in a first wiring and a second wiring.

FIGS. 3A to 3H show production process views of a modified example (embodiment in which a second wiring is thinner than a first wiring) of the production method shown in FIGS. 1C to 1J:

FIG. 3A illustrating a fifth step of forming a first resist,

FIG. 3B illustrating a sixth step of forming the first wiring,

FIG. 3C illustrating a seventh step of removing the first resist,

FIG. 3D illustrating an eighth step of forming a second resist,

FIG. 3E illustrating a ninth step of forming the second wiring,

FIG. 3F illustrating a step of removing the second resist,

FIG. 3G illustrating a tenth step of removing a seed film, and

FIG. 3H illustrating a third step of forming a cover insulating layer.

FIGS. 4A to 4G show production process views of a production method of Comparative Example 1:

FIG. 4A illustrating a step of forming s first resist having a first opening portion and a second opening portion,

FIG. 4B illustrating a step of simultaneously forming a first wiring and an other-side portion of a second wiring,

FIG. 4C illustrating a step of removing the first resist,

FIG. 4D illustrating a step of newly forming a seed film,

FIG. 4E illustrating a step of forming a second resist,

FIG. 4F illustrating a step of forming a one-side portion of the second wiring, and

FIG. 4G illustrating a step of removing the second resist.

FIGS. 5A to 5B show a part of production process views of a production method of Comparative Example 2 in which a one-side portion in a thickness direction is narrower than an other-side portion in a second wiring:

FIG. 5A illustrating a view for describing a tolerance between the other-side portion in the thickness direction of the second wiring and a second opening portion, and

FIG. 5B illustrating a process view of forming the one-side portion in the thickness direction of the second wiring.

FIGS. 6A to 6B show a part of production process views of a production method of Comparative Example 3 in which a one-side portion in a thickness direction is wider than an other-side portion in a second wiring:

FIG. 6A illustrating a view for describing a tolerance between the other-side portion in the thickness direction of the second wiring and a second opening portion, and

FIG. 6B illustrating a process view of forming the one-side portion in the thickness direction of the second wiring.

### DESCRIPTION OF EMBODIMENTS

### One Embodiment

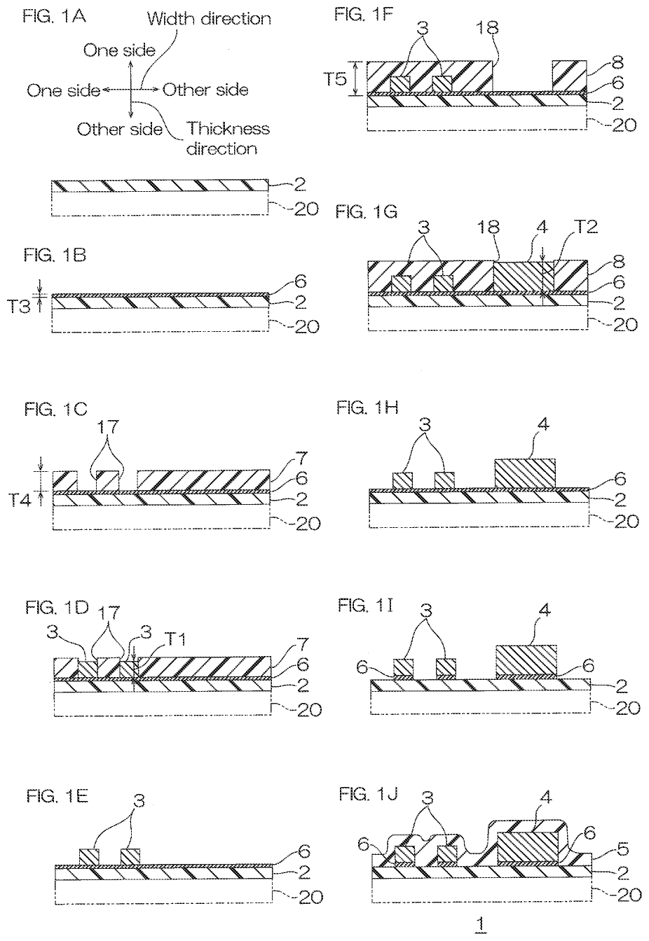

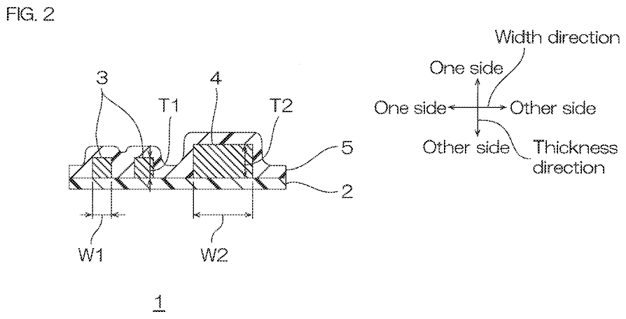

One embodiment of a method for producing a wiring circuit board of the present invention is described with reference to FIGS. 1A to 2.

As shown in FIGS. 1J and 2, a wiring circuit board 1 obtained by the production method has a predetermined thickness, and has a long flat belt shape. Specifically, the wiring circuit board 1 extends in a depth direction on the plane of the sheet. The wiring circuit board 1 includes a base insulating layer 2 as one example of a base insulating layer, a first wiring 3, a second wiring 4, and a cover insulating layer 5.

The base insulating layer 2 has the same shape as the wiring circuit board 1 when viewed from the top. One surface in a thickness direction of the base insulating layer 2 is flat. Examples of a material for the base insulating layer 2 include insulating resins such as polyimide. The base insulating layer 2 has a thickness of, for example, 5 μm or more, and for example, 30 μm or less.

The first wiring 3 is disposed on one surface in the thickness direction of the base insulating layer 2. The plurality of first wirings 3 are, for example, disposed spaced apart from each other in a width direction at a. one-side portion in the width direction (direction perpendicular to the thickness direction and a longitudinal direction) of the base insulating layer 2. Each of the plurality of first wirings 3 has a generally rectangular shape in a cross section along the width direction and the thickness direction. Specifically, the first wiring 3 transmits, for example, an electrical signal (for example, a weak current of below 10 mA, furthermore, below 1 mA). Examples of a material for the first wiring 3 include conductors such as copper, silver, gold, chromium, nickel, and titanium, and alloys of these.

The first wiring 3 has a thickness T1 of, for example, 25 μm or less, preferably 20 μm or less, more preferably 15 μm or less, and for example, 1 μm or more. The first wiring 3 has a width W1 of, for example, 5 μm or more, and for example, 50 μm or less.

The second wiring 4 is disposed spaced apart from the first wiring 3 in the width direction on one surface in the thickness direction of the base insulating layer 2. The second wiring 4 is provided independently from the first wiring 3. Specifically, the single second wiring 4 is, for example, disposed in an other-side portion in the width direction of the base insulating layer 2. Further, the second wiring 4 is formed in one layer. The second wiring 4 has a generally rectangular shape in a cross section along the width direction and the thickness direction. The second wiring 4 transmits, for example, a power supply current (for example, a large current of 10 mA or more, furthermore, 100 mA or more). Examples of a material for the second wiring 4 include conductors such as copper and chromium, and alloys of these. Preferably, the material for the second wiring 4 is the same as that for the first wiring 3.

The second wiring 4 is thicker than the first wiring 3 in the present embodiment. Specifically, the second wiring 4 has a thickness T2 of, for example, 10 μm or more, preferably 15 μm or more, more preferably 20 μm or more, and for example, 500 μm or less. A ratio (T2/T1) of the thickness T2 of the second wiring 4 to the thickness T1 of the first wiring 3 is, for example, 1.25 or more, preferably 1.5 or more, more preferably 1.8 or more, even more preferably 2 or more, and for example, 100 or less.

A width W2 of the second wiring 4 may be the same or larger than the width W1 of the first wiring 3, and is, for example, 5 μm or more, preferably 10 μm or more, more preferably 20 μm or more, and for example, 100 μm or less.

The cover insulating layer 5 covers the first wiring 3 and the second wiring 4. Specifically, the cover insulating layer 5 is disposed on one surfaces in the thickness direction and both side surfaces in the width direction of the first wiring 3 and the second wiring 4, and one surface in the thickness direction around the first wiring 3 and the second wiring 4 in the base insulating layer 2. As a material for the cover insulating layer 5, the same material as that illustrated in the base insulating layer 2 is used. A thickness of the cover insulating layer 5 is a length between one surface in the thickness direction of the cover insulating layer 5 and one surface in the thickness direction of the first wiring 3, and a length between one surface in the thickness direction of the cover insulating layer 5 and one surface in the thickness direction of the second wiring 4. The cover insulating layer 5 has a thickness of, for example, 5 μm or more, and for example, 30 μm or less.

As shown in FIGS. 1A to 1J, the production method includes a first step of forming the base insulating layer 2, a second step of forming the first wiring 3 and the second wiring 4, and a third step of forming the cover insulating layer 5.

As shown in FIG. 1A, in the first step, for example, the base insulating layer 2 having the above-described shape is formed from an insulating resin such as polyimide. Specifically, the above-described insulating resin composition is applied to a substrate, and a photosensitive base layer is formed to be subjected to photolithography, thereby forming the base insulating layer 2.

As shown in FIGS. 1B to 1I, in the second step, the first wiring 3 and the second wiring 4 are formed in this order on one surface in the thickness direction of the base insulating layer 2. That is, as shown in FIG. 1E, first, the first wiring 3 is formed on one surface in the thickness direction of the base insulating layer 2, and thereafter, as shown in FIG. 1I, the second wiring 4 is formed on one surface in the thickness direction of the base insulating layer 2.

Specifically, the second step includes a fourth step of forming the seed film 6 (ref FIG. 1B), a fifth step of forming a first resist 7 (ref: FIG. 1C), a sixth step of forming the first wiring 3 by plating (ref: FIG. 1D), a seventh step of removing the first resist 7 (ref: FIG. 1E), an eighth step of forming a second resist 8 (ref: FIG. 1F), a ninth step of forming the second wiring 4 by plating (ref FIG. 1G), a tenth step of removing the second resist 8 (ref FIG. 1H), and an eleventh step of removing a seed film 6 (ref FIG. 1I). As shown in FIGS. 1B to 1I, the fourth step to the eleventh step are carried out in order.

As shown in FIGS. 1B, in the fourth step, the seed film 6 is formed on one surface in the thickness direction of the base insulating layer 2. The seed film 6 is in contact with the entire one surface in the thickness direction of the base insulating layer 2. The seed film 6 is, for example, formed by a film-forming method such as sputtering arid plating (electroless plating etc.), preferably by sputtering.

As a material for the seed film 6, the above-described material illustrated in the first wiring 3 and the second wiring 4 is used. The seed film 6 has a thickness T3 of, for example, 50 nm or more, preferably 75 nm or more, more preferably 100 nm or more, and for example, 1000 nm or less, preferably 300 nm or less.

When the thickness T3 of the seed film 6 is the above-described lower limit or more, the seed film 6 exposed from the first wiring 3 can reliably remain along with the removal of the first resist 7 in the subsequent seventh step (FIG. 1E). On the other hand, when the thickness T3 of the seed film 6 is the above-described upper limit or less, it is possible to form the seed film 6 in a short time.

As shown in FIG. 1C, in the fifth step, the first resist 7 is formed in a reversed pattern of the first wiring 3 on one surface in the thickness direction of the seed film 6. For example, a photosensitive dry film resist is disposed on the entire one surface in the thickness direction of the seed film 6, and thereafter, the photosensitive dry film resist is subjected to photolithography, thereby forming the first resist 7 in the above-described pattern. The first resist 7 has a first opening portion 17 corresponding to a planned formation position of the first wiring 3. The first opening portion 17 penetrates the first resist 7 in the thickness direction. The first opening portion 17 exposes one surface in the thickness direction of the seed film 6. A thickness T4 of the first resist 7 exceeds, for example, the thickness T1 of the first wiring 3.

As shown in FIG. 1D, in the sixth step, the first wiring 3 is formed on one surface in the thickness direction of the seed film 6 exposed from the first opening portion 17 of the first resist 7 by plating. In the sixth step, an electric power is supplied to the seed film 6, while the base insulating layer 2, the seed film 6, and the first resist 7 are immersed in a plating solution, thereby forming the first wiring 3 on one surface in the thickness direction of the seed film 6 exposed from the first opening portion 17.

As shown in FIG. 1E, in the seventh step, the first resist 7 is removed. For example, the first resist 7 is removed by etching, peeling, and the like so that the seed film 6 remains.

At this time, the seed film 6 exposed from the first wiring 3 is thinner than the seed film 6 corresponding to the first wiring 3 by, for example, 10 to 100 nm due to the above-described removal of the first resist 7. That is, the seed film 6 corresponding to the second wiring 4 to be formed in a subsequent step is thinner than the seed film 6 corresponding to the first wiring 3 by, for example, 10 to 100 nm.

As shown in FIG. 1F, in the eighth step, the second resist 8 is formed. The second resist 8 is formed in a reversed pattern of the second wiring 4 on one surface in the thickness direction of the seed film 6 so as to mask (cover) the first wiring 3. For example, a photosensitive dry film resist is disposed on one surface in the thickness direction of the seed film 6, and one surface in the thickness direction and both side surfaces in the width direction of the first wiring 3. Thereafter, the photosensitive dry film resist is subjected to photolithography, thereby forming the second resist 8 in the above-described pattern. The second resist 8 has a second opening portion 18 corresponding to a planned formation position of the second wiring 4. The second opening portion 18 penetrates the second resist 8 in the thickness direction. The second opening portion 18 exposes one surface in the thickness direction of the seed film 6. A thickness T5 of the second resist 8 exceeds the thickness T2 of the second wiring 4. The thickness T5 of the second resist 8 is, for example, thicker than the thickness T4 of the first resist 7. A ratio (T5/T4) of the thickness T5 of the second resist 8 to the thickness T4 of the first resist 7 is, for example, 2 or more, furthermore 3 or more, and for example, 20 or less, furthermore 10 or less.

As shown in FIG. 1G, in the ninth step, the second wiring 4 is formed on one surface in the thickness direction of the seed film 6 exposed from the second opening portion 18 of the second resist 8 by plating. In the ninth step, an electric power is supplied to the seed film 6, while the base insulating layer 2, the seed film 6, the first wiring 3, and the second resist 8 are immersed in a plating solution, thereby forming the second wiring 4 on one surface in the thickness direction of the seed film 6 exposed from the second opening portion 18. Both the first wiring 3 and the second wiring 4 are provided on one surface in the thickness direction of the seed film 6 (on the same plane). Further, the seed film 6 of the first wiring 3, and the seed film 6 of the second wiring 4 are common, and the same layer.

As shown in FIG. 1H, in the tenth step, the second resist 8 is removed. For example, the second resist 8 is removed by etching, peeling, and the like.

As shown in FIG. 1I, in the eleventh step, the seed film 6 exposed from the first wiring 3 and the second wiring 4 is removed. For example, the seed film 6 is removed by a removal method such as etching and peeling.

Both the seed film 6 between the base insulating layer 2 and the first wiring 3, and the seed film 6 between the base insulating layer 2 and the second wiring 4 are not removed, and remain. As shown in FIG. 1I, both the interface between the seed film 6 and the first wiring 3, and the interface between the seed film 6 and the second wiring 4 are observed, and clearly drawn. Alternatively, as shown in FIG. 2, the above-described interface may not be observed, and obscure, and the seed film 6 may be also integrated with the first wiring 3 and the second wiring 4, and included in each of the first wiring 3 and the second wiring 4.

By the above-described second step in which the fourth step to the eleventh step are carried out, the first wiring 3 and the second wiring 4 are formed in order on one side in the thickness direction of the base insulating layer 2.

As shown in FIG. 1J, in the third step, the cover insulating layer 5 is formed on one surface in the thickness direction of the base insulating layer 2 so as to cover the first wiring 3 and the second wiring 4. Specifically, the above-described insulating resin composition is applied to one surfaces in the thickness direction of the base insulating layer 2, the first wiring 3, and the second wiring 4, thereby forming a photosensitive cover layer. The resulting photosensitive cover layer is subjected to photolithography, thereby forming the cover insulating layer 5.

Thus, the wiring circuit board 1 including the base insulating layer 2, the first wiring 3, the second wiring 4, the seed film 6 corresponding to the first wiring 3 and the second wiring 4, and the cover insulating layer 5 is produced.

### Function and Effect of One Embodiment

Then, in the production method, in the second step, as shown in FIGS. 1D and 1G, since each of the first wiring 3 and the second wiring 4 having different thicknesses from each other is formed using each of the first resist 7 and the second resist 8, it is possible to form the first wiring 3 and the second wiring 4 having a desired shape, arrangement, and size.

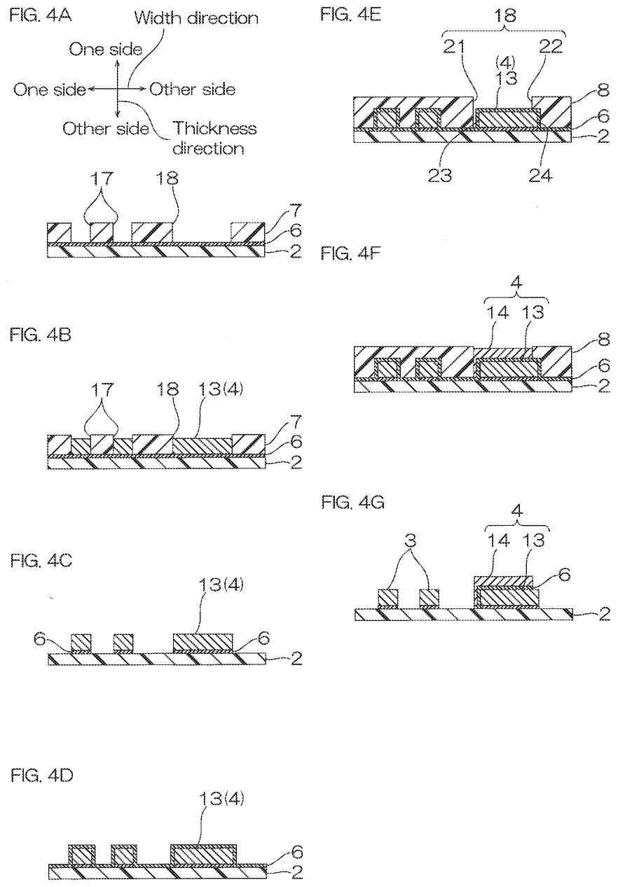

In order to further develop the above-described understanding, a method of Comparative Example 1 corresponding to the production method of Patent Document 1 is described using FIGS. 4A to 4G.

In Comparative Example 1, as shown in FIG. 4A, in the fifth step, the first resist 7 having the first opening portion 17 and the second opening portion 18 is formed.

Then, as shown in FIG. 4B, in the sixth step, the first wiring 3, and a thickness directional other-side portion 13 of the second wiring 4 are simultaneously formed by plating.

As shown in FIG. 4C, in the seventh step, the seed film 6 is removed when the first resist 7 is removed. As shown in FIG. 4D, thereafter, the seed film 6 is formed again on one surface in the thickness direction of the base insulating layer 2, and one surface in the thickness direction and both side surfaces of the first wiring 3 and the thickness directional other-side portion 13.

As shown in FIG. 4E, in the eighth step, the second resist 8 having the second opening portion 18 is formed.

However, the position of the second opening portion 18 of the second resist 8, and the position of the thickness directional other-side portion 13 of the second wiring 4 may be deviated. That is, there is a tolerance regarding the position between the second opening portion 18 of the first resist 7 in the fifth step shown in FIG. 4A and the second opening portion 18 of the second resist 8 in the eighth step shown in FIG. 4E. Then, a deviation occurs between the thickness directional other-side portion 13 of the second wiring 4 and the second opening portion 18 of the second resist 8.

In Comparative Example 1, regarding the tolerance between the thickness directional other-side portion 13 and the second opening portion 18, a one-side inner-side surface 21 of the second opening portion 18 is deviated toward one side in the width direction with respect to a width directional one-side surface 23 of the thickness directional other-side portion 13. An other-side inner-side surface 22 of the second opening portion 18 is deviated toward one side in the width direction with respect to the width directional other-side surface 24 of the thickness directional other-side portion 13.

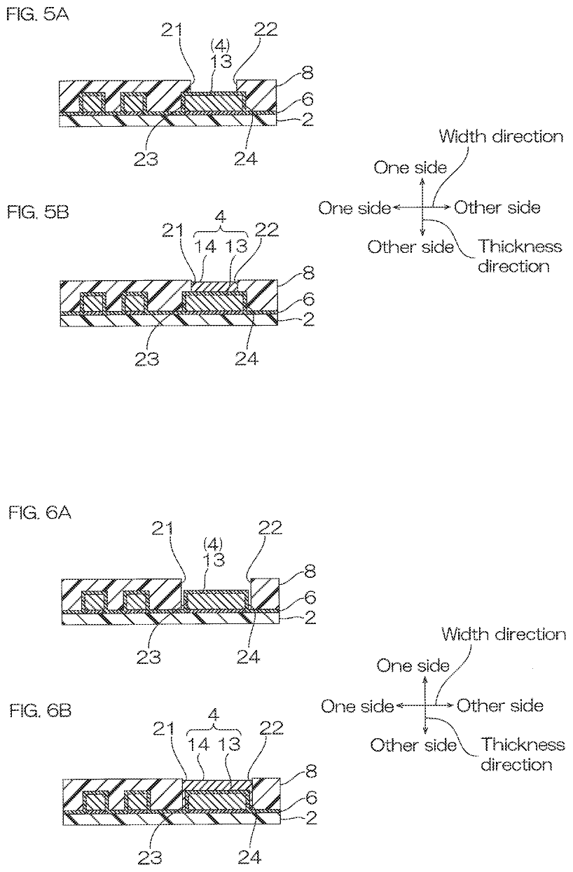

The deviation is not limited to the description above, and for example, in Comparative Example 2, as shown in FIG. 5A, the one-side inner-side surface 21 of the second opening portion 18 is deviated toward the other side in the width direction with respect to the width directional one-side surface 23 of the thickness directional other-side portion 13. In Comparative Example 3, as shown in FIG. 6A, the other-side inner-side surface 22 of the second opening portion 18 is deviated toward the other side in the width direction with respect to the width directional other-side surface 24 of the thickness directional other-side portion 13.

Then, as shown in FIG. 4F (furthermore, FIGS. 5B and 6B), in the ninth step, a deviation occurs between both end surfaces in the width direction of a thickness directional one-side portion 14 in the second wiring 4 which is formed by plating, and both end surfaces in the width direction of the thickness directional other-side portion 13. Therefore, as shown in FIG. 4G, it is not possible to form the second wiring 4 having a desired shape, arrangement, and size.

In Comparative Example 1, the one-side portion 14 is deviated toward one side in the width direction with respect to the other-side portion 13. In Comparative Example 2, as shown in FIG. 5B, the one-side portion 14 is narrower than the thickness directional other-side portion 13. In Comparative Example 3, as shown in FIG 6B, the one-side portion 14 is wider than the thickness directional other-side portion 13.

However, in the present embodiment, as shown in FIG. 1F, since the second wiring 4 is formed at one time using only the second resist 8 without using the first resist 7, it is possible to form the second wiring 4 having a desired shape, arrangement, and size.

Further, as shown in FIG. 1E, in the seventh step of the production method, since the first resist 7 is removed so that the seed film 6 remains, it is not necessary to form the seed film 6 again before forming the second resist 8 shown in FIG. 1F (ref: step of FIG. 4D). Therefore, the seed film 6 used in the plating in the sixth step can be reused as it is for the plating in the ninth step shown in FIG. 1G. As a result, it is possible to form the second wiring 4 with few steps.

Further, in this embodiment, since the second wiring 4 is independent of the first wiring 3, the second wiring 4 can be used for a different application from the first wiring 3. Specifically, the first wiring 3 is used as a signal wiring, and the second wiring 4 which is thicker than the first wiring 3 is used as a power supply wiring.

Furthermore, in this embodiment, as shown in FIG. 1E, in the seventh step, in the step of removing the first resist 7, even when a removal method such as etching and peeling is carded out, the seed film 6 having the thickness T3 of the above-described lower limit or more can reliably remain. Therefore, in the ninth step, it is possible to stably carry out the plating in forming the second wiring 4. Further, it is possible to form the seed film 6 having the thickness T3 of the above-described upper limit or less in a short time.

### AMODIFIED EXAMPLES

In each modified example below, the same reference numerals are provided for members and steps corresponding to each of those in the above-described one embodiment, and their detailed description is omitted. Each modified example can achieve the same function and effect as that of one embodiment unless otherwise specified. Furthermore, one embodiment and the modified example thereof can be appropriately used in combination.

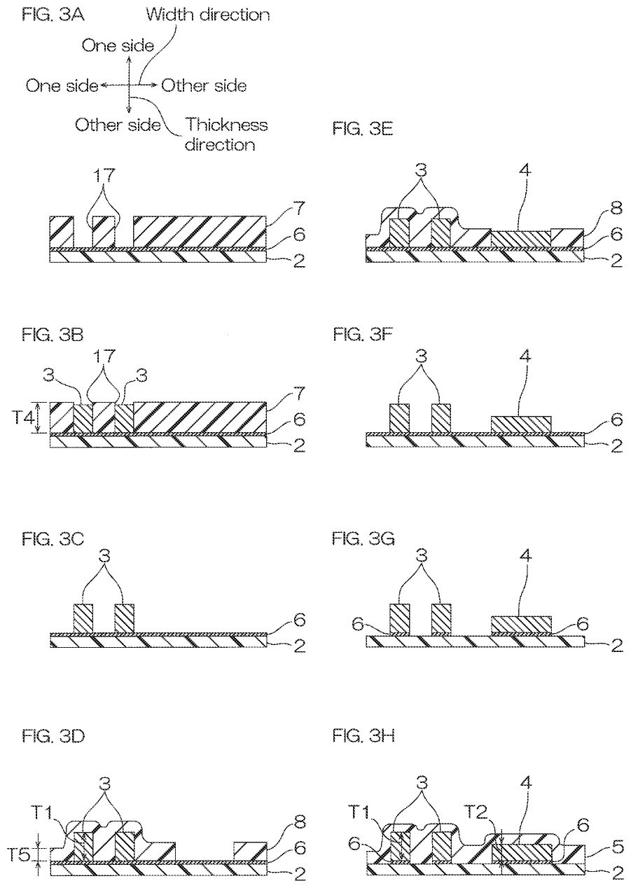

In the wiring circuit board 1 obtained by the production method of the modified example, as shown in FIG. 3H, the first wiring 3 is thicker than the second wiring 4.

Considering that, as shown in FIG. 3B, the first resist 7 has the thickness T4 corresponding to the first wiring 3, and also, as shown in FIG. 3E, the second resist 8 has the thickness T5 corresponding to the second wiring 4, as shown in FIG. 3D, the second resist 8 is usually thinner than the thickness T1 of the first wiring 3.

Therefore, it is difficult to cover (mask) the end portion in the width direction of one end portion in the thickness direction of the first wiring 3 by the second resist 8. Then, when there is an omission of masking of the first wiring 3 by the second resist 8, it may lead to plating growth in a portion in which the plating growth is not desired, in particular, the end portion in the width direction of one end portion in the thickness direction of the first wiring 3.

In contrast, in one embodiment, as shown in FIG. 1F, when the second wiring 4 is thicker than the first wiring 3, the thick second resist 8 can easily and reliably cover (mask) the first wiring 3 which is thinner than the second wiring 4. Therefore, it is possible to suppress the above-described plating growth.

As shown by a phantom line of FIG. 1J, the wiring circuit board 1 may further include a metal support board 20. The metal support board 20 is disposed on the other surface in the thickness direction of the base insulating layer 2. Examples of a material for the metal support board 20 include metals such as iron, copper, and alloys (stainless steel, copper alloy, etc.). The thickness of the metal support board 20 is not particularly limited. In the first step, as shown by the phantom line of FIG. 1A, the metal support board 20 is prepared, and the base insulating layer 2 is disposed on one surface in the thickness direction thereof.

The tenth step and the eleventh step can be carried out without distinction. Specifically, when the second resist 8 is removed, the seed film 6 is unintentionally removed.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The wiring circuit board of the present invention is used for various industrial applications.

### DESCRIPTION OF REFERENCE NUMERALS

1 Wiring circuit board

3 First wiring

4 Second wiring

6 Seed film

7 First resist

8 Second resist

T3 Thickness of seed film

1. A method for producing a wiring circuit board comprising:
a first step of forming an insulating layer, and
a second step of forming a first wiring and a second wiring having different thicknesses from each other in order on one surface in a thickness direction of the insulating layer, wherein
the second step includes, in order,
a step of forming a seed film on one surface in the thickness direction of the insulating layer,
a step of forming a first resist in a reversed pattern of the first wiring on one surface in the thickness direction of the seed film,
a step of forming the first wiring on one surface in the thickness direction of the seed film exposed from the first resist by plating,
a step of removing the first resist,
a step of forming a second resist in a reversed pattern of the second wiring on one surface in the thickness direction of the seed film so as to cover the first wiring,
a step of forming the second wiring on one surface in the thickness direction of the seed film exposed from the second resist by plating,
a step of removing the second resist, and
a step of removing the seed film exposed from the first wiring and the second wiring.

2. The method for producing a wiring circuit board according to claim 1, wherein
in the step of removing the first resist, the seed film remains.

3. The method for producing a wiring circuit board according to claim 1, wherein
the second wiring is thicker than the first wiring.

4. The method for producing a wiring circuit board according to claim 1, wherein
the second wiring is independent of the first wiring.

5. The method for producing a wiring circuit board according to claim 1, wherein
the seed film has a thickness of 50 nm or more and 1000 nm or less.
